(19) United States
(12) Patent Application Publication
(10) Pub. No.: US 2025/0010427 A1
(43) Pub. Date: Jan. 9, 2025

(54) METHOD AND APPARATUS FOR PROCESSING DIAMOND SURFACE

(71) Applicant: Element Six Technologies Limited, Didcot, Oxfordshire (GB)

(72) Inventors: Christopher John KELLY, Didcot, Oxfordshire (GB); David William JAMES, Didcot, Oxfordshire (GB)

(21) Appl. No.: 18/710,290

(22) PCT Filed: Nov. 14, 2022
(86) PCT No.: PCT/EP2022/081753

§ 371 Date: May 15, 2024

(30) Foreign Application Priority Data
Nov. 16, 2021 (GB) 2116477.7

(51) Int. Cl. B24B 49/04; B24B 9/16; B24B 49/12

(52) U.S. Cl. CPC B24B 49/04; B24B 9/161; B24B 9/168; B24B 49/12

(57) ABSTRACT

There is provided a method and apparatus for processing a diamond surface. The method comprises: i. locating a diamond material having a first surface and a second, opposite surface, in a holder, the holder located at the end of a positioning arm; ii. processing the first surface on a rotating wheel; iii. while the diamond material is in the holder, measuring an angle of the first surface relative to the second surface; iv. repeating steps (ii) and (iii) until a desired angle is achieved.

### FIELD OF THE INVENTION

This disclosure relates to a method and apparatus for processing a diamond surface.

### BACKGROUND

CVD diamond material has excellent optical properties, and has often been used for optical applications, such as optical windows for infrared systems, as Raman lasers or as etalons for investigating frequency variations. There has historically been significant work on modifying the bulk material properties of the diamond. However, few processes have been developed for processing diamond parts to the tolerances needed for optical applications.

Optical applications such as solid etalons with two partially reflecting surfaces often need surfaces processed to exceedingly low surface roughness, excellent flatness, and high levels of parallelism, since variations of the same order as the wavelength of light will impact the light passing through them. This means that whilst tolerances of mechanical parts are often measured in microns, for optical parts they must be measured in nanometres, or even angstroms.

Achieving this sort of tolerance is feasible for other optical materials, often using diamond tools for preparing the surface. High levels of flatness and tight tolerances can be achieved, for example, by double sided lapping.

However, the extreme hardness of diamond makes it extremely challenging to shape. Typically, diamond has to be processed using other forms of diamond, such as diamond grit or wheels with diamond grit embedded. However, the tight tolerances usually required in optics can be hard to meet, as the tools wear as quickly as the part, and there can be significant heat created causing expansion of part and tool beyond the required tolerances. Furthermore, if a very hard tool (e.g. a sintered diamond tool) is used to process a diamond optical part, then the diamond optical part will typically sustain a high level of sub-surface damage due to the hard impact on the brittle material.

Scaife polishing has been used to polish diamonds on a single rotating disc. The disc is coated with a mixture of oil and diamond dust. A rigid arm is used to hold a diamond sample to be polished in a holder (often referred to as a tang). The position of the arm can be adjusted to move a diamond into the required position for polishing. A problem with the scaife technique is that it can be difficult to achieve a high degree of parallelism of a diamond plate, because the rigid arm has a bending moment, which can introduce a slight angle to the diamond in contact with the scaife wheel. The same issue arises when it is desired to process diamond with two surfaces at a desired angle from one another.

Standard measurement techniques such as use of an interferometer in the Fizeau setup involve removing the diamond part from the holder during the processing. To then correct any measured errors, the diamond part needs to be remounted into the holder, a process by which further errors can be introduced.

### SUMMARY OF THE INVENTION

While high levels of parallelism have been reported using scaife techniques (e.g. WO2004046427), this requires a very laborious and time-consuming process because the diamond must be polished, removed from the tang, measured for parallelism, and returned to the tang for further polishing. Other polishing techniques, such as polishing between two parallel plates, can give a high degree of parallelism but these tend to introduce sub-surface damage. Similarly, processing diamond to accurately form an angle between two surfaces encounters the same problems.

It is an object of the present invention to provide a method of forming diamond with a high degree of parallelism and low subsurface damage.

According to a first aspect, there is provided a method of processing a diamond surface. The method comprises:
i. locating a diamond material having a first surface and a second, opposite surface, in a holder, the holder located at the end of a positioning arm;
ii. processing the first surface on a rotating wheel;
iii. while the diamond material is in the holder, measuring an angle of the first surface relative to the second surface;
iv. repeating steps (ii) and (iii) until a desired angle is achieved.

As an option, the method further comprises, after step (iii), making an adjustment to an angle at which the diamond material is held relative to the rotating wheel.

The rotating wheel is optionally a scaife polishing wheel.

Where a diamond plate with parallel surfaces is required, the desired angle is 0°.

The diamond material optionally comprises any of natural diamond, high-pressure high-temperature (HPHT) diamond and chemical vapour deposition (CVD) diamond.

The diamond material optionally comprises any of single crystal diamond and polycrystalline diamond.

The angle is optionally measured the angle using a non-contact optical technique. Examples of such a non-contact technique include any of a spectral reflectance technique, an interferometer and an autocollimator. Where an autocollimator is used, it is optionally selected from any one of a visual autocollimator, an electric autocollimator, a digital autocollimator and a laser autocollimator. Where a visual autocollimator is used, the method further comprises the visual autocollimator displaying a first and a second illuminated reflected spot from the first surface and the second surface respectively, wherein an alignment of the first and second spots indicates the angle.

Optionally, an achieved angle is selected from any of no more than +/−10 arc seconds, no more than +/−5 arc seconds, and no more than +/−2 arc seconds from the desired angle.

The diamond material optionally has a surface roughness Ra measured by white light interferometry selected from any one of less than 1.0 nm, less than 0.8 nm and less than 0.5 nm.

According to a second aspect, there is provided an apparatus for processing a diamond surface, the apparatus comprising a rotating wheel, a positioning arm located in proximity to the rotating wheel, a holder located on the positioning arm, the holder being configured to hold a diamond material and to allow the diamond material to be pressed against the rotating wheel, and a device configured to measure an angle between a first surface and a second, opposite surface of the diamond material while the diamond material is attached to the holder.

The rotating wheel is optionally a scaife polishing wheel.

The device is optionally configured to measure the angle between the first surface and the second, opposite surface of the diamond material while the diamond material is attached to the holder uses a non-contact optical technique.

As an option, the non-contact optical technique is selected from any of a spectral reflectance technique and an interferometer.

The device is optionally configured to measure the angle between the first surface and the second, opposite surface of the diamond material while the diamond material is attached to the holder comprises any one of a visual autocollimator, an electric autocollimator, a digital autocollimator and a laser autocollimator. Where the device is a visual autocollimator, it is optionally configured to display a first and a second illuminated reflected spot from the first surface and the second surface respectively, wherein an alignment of the first and second spots indicates the angle.

### BRIEF DESCRIPTION OF THE DRAWINGS

The invention will now be more particularly described, by way of example only, with reference to the accompanying drawings, in which:

FIG. 1 is a flow diagram illustrating exemplary steps in processing a diamond material;

FIG. 2 illustrates schematically in a block diagram an exemplary apparatus for processing diamond material;

FIG. 3 illustrates schematically illuminated light spots reflected from surfaces of the diamond material; and

FIG. 4 illustrates schematically side elevation cross section views of exemplary angles.

Throughout the description, similar parts have been assigned the same reference numerals, and a detailed description is omitted for brevity.

### DETAILED DESCRIPTION

The inventors have found that the angle between two surfaces of diamond can be measured in-situ while it is attached to the holder on the end of the rigid arm using a device such as an autocollimator. A diamond plate has two main surfaces, a first surface and a second opposite surface. The autocollimator can be used to measure the angle between these two surfaces. This finds particular use in measuring the parallelism of two surfaces of diamond, but may also be used to accurately measure an angle between two surfaces.

The autocollimator projects an image such as a light disc into the diamond held in the holder. Reflectance occurs at the first diamond surface, and also at the second diamond surface. The alignment of the two reflected images can be used to calculate the angle of deviation from parallelism between the two surfaces.

Several types of autocollimator are available; visual autocollimators, in which the reflected images are compared by an operator using an eye-piece, can typically measure angles as small as 1 arc-second Electronic and digital autocollimators can have up to 100 times more resolution. Laser autocollimators also allow for very accurate measurements of angles between the two surfaces.

Note that other techniques may be used to measure the parallelism between two surfaces in the diamond material. For example, WO2004046427 describes a technique in which parallelism is measured using a Zygo GPI phase shifting 633 nm laser Fizeau-type interferometer. By comparing a transmitted wavefront fringe pattern from a diamond material in the beam path with a pattern measured without any diamond material in the beam path, the change in direction of and distance between successive fringes can be computed and from this computation, the deviation from parallelism between the two polished surfaces of the diamond material can be determined.

These techniques can be used without removing the diamond material from the holder. This means that an iterative process of polishing can achieve a very high degree of parallelism, as the parallelism cab be measured without removing the diamond material from the holder, meaning that very small adjustments can be made to the polishing process and the diamond need not be repeatedly removed and reattached top the holder, leading to possible alignment issues and being a more time-consuming process.

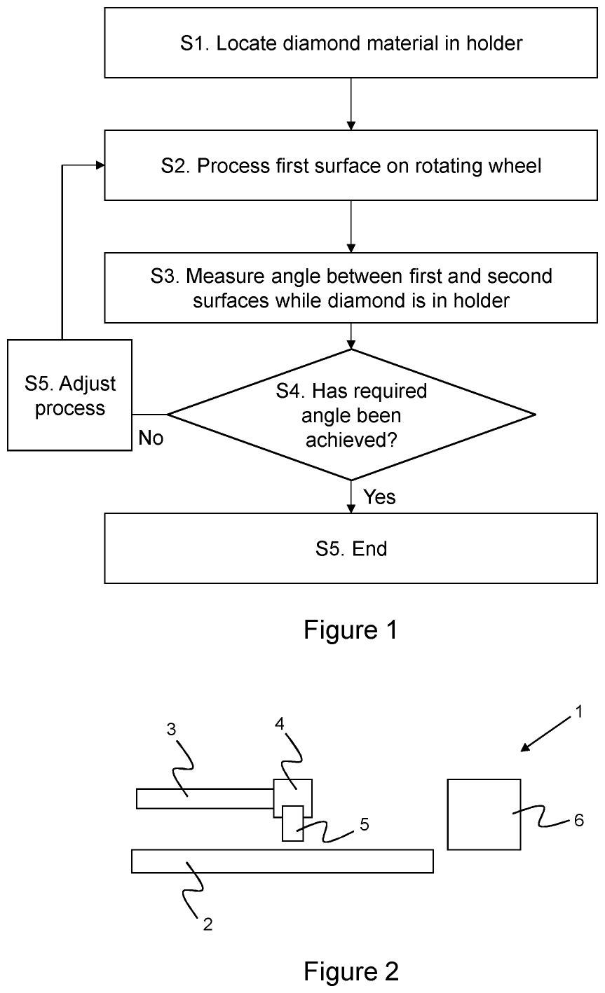

Referring to FIG. 1 herein, there is shown a flow diagram illustrating exemplary steps for processing a diamond plate. The following numbering corresponds to that of FIG. 1:
S1. A diamond material such as single crystal diamond is located in a holder, which is typically a tang on a mechanical arm.
S2. The diamond material is pressed onto a rotating wheel, such as a cast iron scaife wheel that has a coating of diamond dust and oil to process the surface while minimising subsurface damage.
S3. While the diamond material is still in-situ on the holder, the angle between of two opposing surfaces is measured using a device such as an autocollimator or an interferometer.
S4. If the required angle has been achieved, the process moves to step S6. If the required angle has not been achieved, the process moves to step S5.
S5. It may be that the process requires no adjustment and further polishing is required. IN this case, the process reverts to step S2. Alternatively, it may be that the processing conditions require some adjustment in order to achieve the desired angle. If so then the required adjustment is made before the process reverts to step S2.
S6. The process ends and the diamond material is removed from the holder.

Turning now to FIG. 2 herein, there is illustrated schematically in a block diagram an exemplary apparatus 1 for processing diamond material. The apparatus 1 comprises a polishing wheel 2. For scaife polishing, the wheel 2 is typically a cast iron wheel coated with oil and diamond dust. A rigid arm 3 is positions above the wheel 2. A holder 4 is located at an end of the rigid arm 3. The holder 4 is configured to hold a diamond material 5 to be processed. A device 6 for measuring the angle between two surfaces of the diamond material 5 is also provided, which provides a non-contact way of measuring the angle between two surfaces of the diamond material 5 while it is in the holder 4.

### EXAMPLES

The following examples show the technique used to measure the parallelism between two surfaces of a diamond, but the skilled person will readily understand that the same techniques can be used to achieve a desired angle between two surfaces.

A scaife wheel was provided with a coating of oil and diamond dust down to sizes of 15 μm, and an autocollimator. The autocollimater was a Micro-Radian Instruments™ MRA-50 visual autocollimator with an emitted beam diameter of 18 mm. The resolution was 5 arc-seconds and the pinhole diameter was 100±5 μm. The eyepiece magnification was 20× and a white LED light source was used.

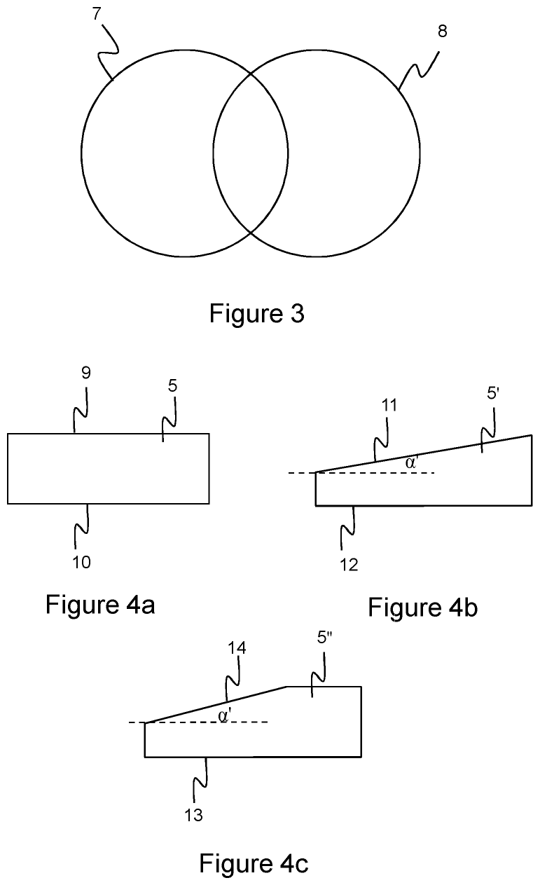

When used to measure single crystal diamond material with nominal dimensions of 6×4×2 mm, a spot size of 100 μm was used to reflect spots from the first surface and the second surface of the diamond material. The spots were inspected visually by an operator using an eyepiece. FIG. 3 illustrates schematically a first illuminated spot 7 reflected from a first surface of the diamond material, and a second illuminated spot 8 reflected from a second surface of the diamond material. When the two spots touch at their circumferences, this indicates a misalignment from parallelism of 100 arc seconds. When the two spots overlap by 50%, this indicates a misalignment from parallelism of 50 arc seconds. Where the two spots overlap completely, this indicates parallelism. In other words, the alignment of the first and second spots indicates the degree of parallelism.

Blurring of the observed spots indicates that the surface from which the spot is reflected is not completely flat or of a good finish. Double spot patterns indicate a double facet. This provides useful feedback to an operator during a polishing operation and allows the operator to adjust the polishing conditions in-situ.

Four exemplary plates were scaife polished using the process described in FIG. 1 and the apparatus described above. The dimensions and parallelism of the plates are shown in Table 1.

TABLE 1
Exemplary single crystal diamond plates

| | | | | Parallelism/ |
|---|---|---|---|---|
| Example | Length mm | Width mm | Thickness mm | arcsec |
| 1 | 6.056 | 4.058 | 2.088 | 5.20 |
| 2 | 6.071 | 4.080 | 2.067 | 7.26 |
| 3 | 6.017 | 4.069 | 2.095 | 3.86 |
| 4 | 6.071 | 4.014 | 2.033 | 7.39 |

All samples had a surface roughness Ra of between 0.4 and 0.9 nm, measured using a white light interferometer.

While the examples about had a thickness of around 2 mm, it has been found that diamond plates with thicknesses as low as 100 μm, 50 μm, 20 μm and 10 μm can be polished in this way with careful handling.

The use of a scaife polishing wheel in combination with the autocollimator allows diamond plates with very high parallelism to be produced quickly and reproducibly. Other non-contact techniques, such as interferometry, can also be used to measure the parallelism of the plates in situ.

Turning now to FIG. 4, there are illustrated exemplary shapes that can be achieved using the above technique. In FIG. 4a, the diamond 5 has a first surface 9 and a second surface 10, and the desired angle between them is 0°; in other words, a high degree of parallelism is required.

FIG. 4b shows a wedge shape in which a surface 11 of the diamond 5′ is processed to have an angle α′ relative to the second surface 12.

FIG. 4c shows a wedge shape in which a surface 14 of the diamond 5″ is processed to have an angle α″ relative to a second surface 13, but the first surface 14 is processed to form a chamfer.

While this invention has been particularly shown and described with reference to embodiments, it will be understood by those skilled in the art that various changes in form and detail may be made without departing from the scope of the invention as defined by the appended claims.

For example, while the above examples refer to a visual autocollimator, it will be appreciated that angles may be measured while in the holder using any suitable technique such as a non-contact optical technique. These include spectral reflectance techniques, interferometers and other forms of autocollimator, such as an electric autocollimator, a digital autocollimator and a laser autocollimator.

It will also be appreciated that the process could to a large extend be automated such that the measured angle is used as feedback to automatically adjust the processing conditions in order to achieve a desired adjust.

1. A method of processing a diamond surface, the method comprising:
i. locating a diamond material having a first surface and a second, opposite surface, in a holder, the holder located at the end of a positioning arm;
ii. processing the first surface on a rotating wheel;
iii. while the diamond material is in the holder, measuring an angle of the first surface relative to the second surface using a non-contact optical technique selected from any of a spectral reflectance technique, an interferometer and an autocollimator;
iv. repeating steps (ii) and (iii) until a desired angle is achieved.

2. The method according to claim 1, further comprising, after step (iii), making an adjustment to an angle at which the diamond material is held relative to the rotating wheel.

3. The method according to claim 1, wherein the rotating wheel is a scaife polishing wheel.

4. The method according to claim 1, wherein the desired angle is 0°.

5. The method according to claim 1, wherein the diamond material comprises any of natural diamond, high-pressure high-temperature (HPHT) diamond and chemical vapour deposition (CVD) diamond.

6. The method according to claim 1, wherein the diamond material comprises any of single crystal diamond and polycrystalline diamond.

7. (canceled)

8. The method according to claim 1, wherein the non-contact optical technique comprises an autocollimator selected from any one of a visual autocollimator, an electric autocollimator, a digital autocollimator and a laser autocollimator.

9. (canceled)

10. The method according to claim 8, wherein the autocollimator is a visual autocollimator, the method further comprising the visual autocollimator displaying a first and a second illuminated reflected spot from the first surface and the second surface respectively, wherein an alignment of the first and second spots indicates the angle.

11. The method according to claim 1, wherein an achieved angle is selected from any of no more than +/−10 arc seconds, no more than +/−5 arc seconds, and no more than +/−2 arc seconds from the desired angle.

12. The method according to claim 1, wherein the diamond material has a surface roughness Ra measured by white light interferometry selected from any one of less than 1.0 nm, less than 0.8 nm and less than 0.5 nm.

13. Apparatus for processing a diamond surface, the apparatus comprising:
a rotating wheel;
a positioning arm located in proximity to the rotating wheel;
a holder located on the positioning arm, the holder being configured to hold a diamond material and to allow the diamond material to be pressed against the rotating wheel;
a device configured to measure an angle between a first surface and a second, opposite surface of the diamond material while the diamond material is attached to the holder using a non-contact optical technique selected from any of a spectral reflectance technique, an interferometer and an autocollimator.

14. The apparatus according to claim 13, wherein the rotating wheel is a scaife polishing wheel.

15. (canceled)

16. (canceled)

17. The apparatus according to claim 13, wherein the device configured to measure the angle between the first surface and the second, opposite surface of the diamond material while the diamond material is attached to the holder comprises any one of a visual autocollimator, an electric autocollimator, a digital autocollimator and a laser autocollimator.

18. The apparatus according to claim 17, wherein the device is a visual autocollimator configured to display a first and a second illuminated reflected spot from the first surface and the second surface respectively, wherein an alignment of the first and second spots indicates the angle.
